(19) United States
(12) Patent Application Publication
(10) Pub. No.: US 2011/0139252 A1
(43) Pub. Date: Jun. 16, 2011

(54) Inverted organic solar cell and method for manufacturing the same

(75) Inventors: Fang-Chung Chen, Zhushan Township (TW); Jyh-Lih Wu, Dongshan Township (TW); Yi Hung, Chiayi City (TW)

(73) Assignee: National Chiao Tung University, Hsinchu (TW)

(21) Appl. No.: 12/805,660

(22) Filed: Aug. 12, 2010

(30) Foreign Application Priority Data
Dec. 10, 2009 (TW) 098142258

(51) Int. Cl. H01L 51/44; H01L 51/48

(52) U.S. Cl. 136/263; 438/82; 257/E51.012

(57) ABSTRACT

An inverted organic solar cell and a method for manufacturing the same are disclosed, wherein the inverted organic solar cell comprises: a substrate; a first electrode disposed on the substrate; an active layer disposed on the first electrode; an optical spacer containing a buffer layer and an optical interfacial layer, wherein the buffer layer is laminated on the active layer, the optical interfacial layer is laminated on the buffer layer, and the buffer layer is disposed between the active layer and the optical interfacial layer; and a second electrode disposed on the optical spacer. The introduction of the optical spacer with a favorable thickness can enhance light absorption in the active layer, and therefore the power conversion efficiency of the organic solar cell can be improved.

### BACKGROUND OF THE INVENTION

1. Field of the Invention

The present invention relates to an inverted organic solar cell and a method for manufacturing the same and, more particularly, to an inverted organic solar cell containing an optical spacer and a method for manufacturing the same.

2. Description of Related Art

Global attention has been sharply concentrated on the depletion of fossil fuels such as coal, gas and oil so alternative fuels are particularly being studied. Furthermore, those fossil fuels produce serious environmental contamination and the need for clean, infinite power sources, such as solar power, is obvious.

In recent years, the developed solar cells have comprised silicon solar cells and organic solar cells. Though the silicon solar cells have good power conversion efficiency, the solar cells made from Si still have disadvantages of excessive size, weight and high production cost. Hence, studies on organic solar cells have been significantly developed, and it is desirable to develop an organic solar cell with high power conversion efficiency.

As shown in FIG. 1A, a conventional organic solar cell comprises: a substrate 10, an ITO electrode 11, a hole transport layer 17, an active layer 13, and a Ca/Al bilayered electrode 16. Herein, the ITO electrode 11 is an anode, the Ca/Al bilayered electrode 16 is a cathode, the material of the hole transport layer 17 usually is a mixture of PEDOT and PSS, and the material of the active layer 13 usually is a mixture of P3HT and PCBM. However, PEDOT used as the hole transport layer 17 is an acidic water-soluble material, which may deteriorate the overall device performance. In addition, the Ca layer of the bilayered electrode 16 is easily oxidized, and the oxidized Ca layer may cause the decrease of power conversion efficiency and the stability of the organic solar cell. Hence, an inverted organic solar cell without using PEDOT and air-sensitive metals is developed to improve the stability of the device.

As shown in FIG. 1B, the conventional inverted organic solar cell comprises: a substrate 10, an ITO electrode 11, an active layer 13, and an Ag electrode. Herein, the ITO electrode 11 is a cathode, the Ag electrode 18 is an anode, and the material of the active layer 13 usually is a mixture of P3HT and PCBM. Because acidic PEDOT is not used in the inverted organic solar cell, there is no problem of the device degradation. Hence, the stability of the inverted organic solar cell is better than the organic solar cell with conventional structure.

Regardless of the organic solar cell with an inverted structure or a conventional structure, the thickness of the active layer is usually less than 250 nm due to the low carrier mobility of the organic material. However, the thin active layer may limit the light absorption, so it is difficult to improve the efficiency of the organic solar cell.

Therefore, it is desirable to provide an inverted organic solar cell, which not only can solve the problem of the device degradation resulting from PEDOT and air-sensitive metals, but also can increase the light absorption, in order to improve the power conversion efficiency of the device.

### SUMMARY OF THE INVENTION

The object of the present invention is to provide an inverted organic solar cell, which has improved stability and good power conversion efficiency.

Another object of the present invention is to provide a method for manufacturing an inverted organic solar cell, to prepare an inverted organic solar cell with good stability and high power conversion efficiency.

To achieve the aforementioned objects, the inverted organic solar cell of the present invention comprises: a substrate; a first electrode disposed on the substrate; an active layer disposed on the first electrode; an optical spacer containing a buffer layer and an optical interfacial layer, wherein the buffer layer is laminated on the active layer, the optical interfacial layer is laminated on the buffer layer, and the buffer layer locates between the active layer and the optical interfacial layer; and a second electrode disposed on the optical spacer.

In addition, the present invention further provides a method for manufacturing the aforementioned inverted organic solar cell, which comprises the following steps: (A) providing a substrate with a first electrode formed thereon; (B) forming an active layer on the first electrode; (C) forming a buffer layer, and an optical interfacial layer in sequence, wherein the buffer layer and the optical interfacial layer together compose an optical spacer; and (D) forming a second electrode on the optical spacer.

According to the inverted organic solar cell and the method for manufacturing the same of the present invention, the term “optical space” is a structure, which can generate an optical interference effect therein to adjust the spatial redistribution of the optical field of the optical field in the device, and to increase the photocurrent of the device.

In addition, according to the inverted organic solar cell and the method for manufacturing the same of the present invention, the optical spacer has a double layer structure containing an optical interfacial layer and a buffer layer. The optical interfacial layer is the main structure for generating the optical interference effect. The buffer layer can achieve the alignment of energy levels between the optical interfacial layer and the active layer, thus improving the electrical properties of the devices. Overall, the power conversion efficiency of the devices can be increased by incorporating an optical spacer.

The method of the present invention is a simple process for manufacturing an inverted organic solar cell with good power conversion efficiency. In addition, the inverted organic solar cell manufactured through the method of the present invention has better stability than the conventional organic solar cell without an inverted structure. Furthermore, according to the inverted organic solar cell of the present invention, even though the thickness of the active layer is optimized, both the light absorption in the active layer and the photocurrent of the device can be increased by incorporating the optical spacer, and thereby the power conversion efficiency of the device can be improved.

According to the inverted organic solar cell and the method for manufacturing the same of the present invention, the material of the buffer layer can be any transparent oxide with high work function. Preferably, the material of the buffer layer is MoO₃, V₂O₅, or NiO. More preferably, the material of the buffer layer is MoO₃. In addition, the thickness of the buffer layer may be 1-40 nm.

In addition, the method for manufacturing the inverted organic solar cell of the present invention may further comprise a step (Al) after the step (A): forming a modification layer on the first electrode, wherein the modification layer locates between the first electrode and the active layer. Hence, the inverted organic solar cell of the present invention may further comprise a modification layer disposed on the first electrode, wherein the modification layer locates between the first electrode and the active layer.

According to the inverted organic solar cell and the method for manufacturing the same of the present invention, the material of the modification layer can be any conductive materials with low work function. Preferably, the material of the modification layer is Cs₂CO₃, ZnO, or titanium oxide (TiOx). In addition, according to the inverted organic solar cell and the method for manufacturing the same of the present invention, the optical interfacial layer may be a transparent material with high conductivity. Preferably, the material of the optical interfacial layer is ITO, IZO, or titanium oxide (TiOx). More preferably, the material of the optical interfacial layer is ITO. In addition, the thickness of the optical interfacial layer may be 1-250 nm. Preferably, the thickness of the optical interfacial layer is 50-150 nm. More preferably, the thickness of the optical interfacial layer is 75-125 nm.

According to the inverted organic solar cell and the method for manufacturing the same of the present invention, the material of the active layer may be poly(3-hexylthiophene) (P3HT), [6,6]-phenyl C61-butyric acid methyl ester (PCBM), poly[2-methoxy-5-(3′-7′-dimethyloctyloxy) 1,4-phenylenevinylene] (MDMO-PPV), or a combination thereof. Preferably, the material of the active layer is a mixture of P3HT and PCBM.

In addition, according to the inverted organic solar cell and the method for manufacturing the same of the present invention, the material of the substrate is not particularly limited, and can be any transparent substrate. Preferably, the substrate is a glass substrate, a quartz substrate, or a plastic substrate.

Furthermore, according to the inverted organic solar cell and the method for manufacturing the same of the present invention, the materials of the first electrode and the second electrode can be any electrode materials usually used in the organic solar cell. For example, the first electrode may be a transparent electrode. Preferably, the first electrode is an ITO electrode, or an IZO electrode. More preferably, the first electrode is an ITO electrode. In addition, the second electrode can be any metal electrode. Preferably, the second electrode is an Ag electrode. The inverted organic solar cell of the present invention does not contain any air-sensitive metals, such as Ca, as an electrode material, so the problem of electrode oxidation can be suppressed. In addition, the Ag electrode not only serves as an anode, but also as a reflection layer to improve the light absorption.

According to the method for manufacturing the inverted organic solar cell of the present invention, each layer of the organic solar cell can be formed through any conventional process usually used for manufacturing the organic solar cell. For example, the active layer may be formed through a spin coating process, a dip coating process, a roll coating process, or a printing process in the step (B); the buffer layer may be formed through an evaporation process in the step (C); the optical interfacial layer may be formed through a sputtering process in the step (C); and the second electrode may be formed through an evaporation process in the step (D).

### BRIEF DESCRIPTION OF THE DRAWINGS

FIG. 1A is a perspective view of a conventional organic solar cell;

FIG. 1B is a perspective view of a conventional inverted organic solar cell;

FIGS. 2A to 2F is cross-sectional views illustrating the process of manufacturing an inverted organic solar cell in a preferred embodiment of the present invention;

FIG. 3 is a perspective view of an inverted organic solar cell in a comparative embodiment of the present invention;

FIG. 4 is a plot of voltage-current density curves of the test examples of the present invention; and

FIG. 5 is a plot of IPCE curves of the test examples of the present invention.

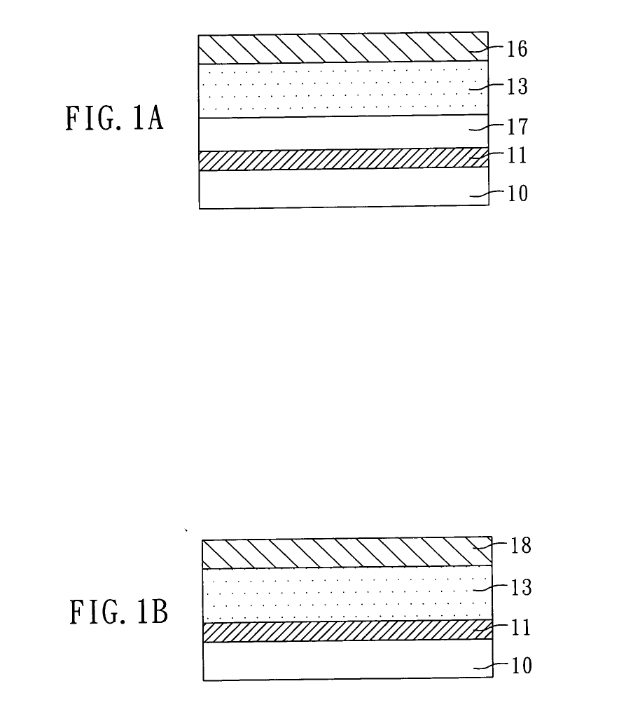

### DETAILED DESCRIPTION OF THE PREFERRED EMBODIMENT

Hereinbelow, the present invention will be described in detail with reference to the Embodiments. The present invention may, however, be embodied in many different forms and should not be construed as being limited to the Embodiments set forth herein. Rather, these Embodiments are provided to fully convey the concept of the invention to those skilled in the art.

### Embodiment 1

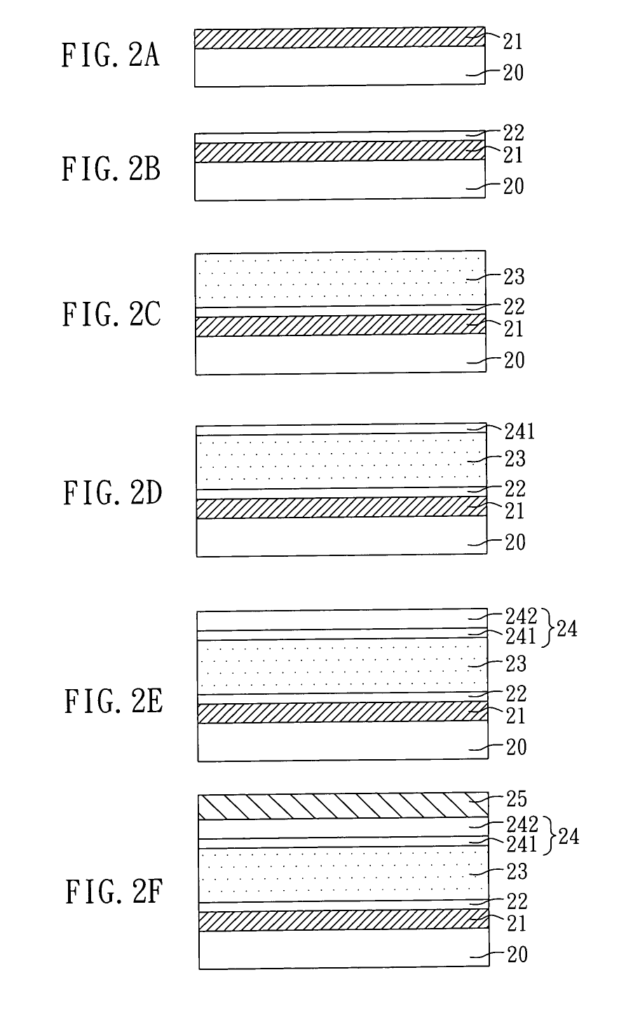

As shown in FIG. 2A, a substrate 20 was provided, and an ITO thin film was grown on the substrate 20, wherein the ITO thin film served as a first electrode 21. In the present embodiment, the substrate 20 is a glass substrate.

As show in FIG. 2B, the first electrode 21 was coated with Cs₂CO₃ through a spin coating process to form a modification layer 22.

Next, a mixture of P3HT and PCBM was deposited on the modification layer 22, and then an annealing process was performed to obtain an active layer 23, as shown in FIG. 2C. In the present invention, the thickness of the active layer 23 was 180 nm.

As shown in FIG. 2D, a MoO₃ layer (a buffer layer 241) was formed on the active layer 23 by an evaporation process. In the present embodiment, the thickness of the buffer layer 241 is 20 nm.

Then, an ITO thin film was formed on the buffer layer 241 by a sputtering process as an optical interfacial layer 242, and the buffer layer 241 and the optical interfacial layer 242 composed an optical spacer 24, as shown in FIG. 2E. In the present embodiment, the thickness of the optical interfacial layer 242 is 50 nm.

Finally, a second electrode 25 was formed by evaporating Ag on the optical spacer 24, as shown in FIG. 2F. In the present embodiment, the thickness of the second electrode 25 is 150 nm.

After the aforementioned process, the inverted organic solar cell prepared in the present embodiment comprises: a substrate 20; a first electrode 21 disposed on the substrate 20; an active layer 23 disposed on the first electrode 21; an optical spacer 24 containing a buffer layer 241 and an optical interfacial layer 242, wherein the buffer layer 241 is laminated on the active layer 23, the optical interfacial layer 242 is laminated on the buffer layer 241, and the buffer layer 241 locates between the active layer 23 and the optical interfacial layer 242; and a second electrode 25 disposed on the optical spacer 24. In addition, the inverted organic solar cell prepared in the present embodiment further comprises: a modification layer 22 disposed on the first electrode 21, wherein the modification layer 22 locates between the first electrode 21 and the active layer 23.

### Embodiment 2

The structure of the inverted solar cell and the manufacturing method of the present embodiment are the same as those described in Embodiment 1, except the thickness of the optical interfacial layer 242 is 100 nm.

### Embodiment 3

The structure of the inverted solar cell and the manufacturing method of the present embodiment are the same as those described in Embodiment 1, except the thickness of the optical interfacial layer 242 is 150 nm.

### Comparative Embodiment

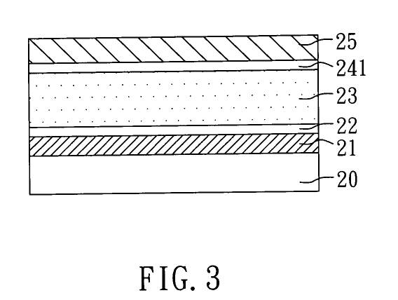

The structure of the inverted solar cell and the manufacturing method of the present comparative embodiment are the same as those described in Embodiment 1, except the manufacturing method of the present comparative does not comprise the step of forming the optical interfacial layer 242. Hence, the inverted solar cell prepared in the present comparative embodiment does not comprise an optical interfacial layer, as shown in FIG. 3.

Hence, the inverted solar cell of the present embodiment comprises: a substrate 20; a first electrode 21 disposed on the substrate 20; a modification layer 22 disposed on the first electrode 21; an active layer 23 disposed on the modification layer 22; a buffer layer 241 disposed on the active layer 23; and a second electrode 25 disposed on the buffer layer 241.

### Test Examples

The short-circuit current density (J_{SC}), open-circuit voltage (V_{OC}), filling factor (FF), and power conversion efficiency (PCE) of the inverted organic solar cells prepared by Embodiments 1-3 and Comparative embodiment were measured under the illumination of AM 1.5 simulated solar light. The testing results are shown in the following table.

| | V_{oc} (V) | J_{sc} (mA cm⁻²) | FF (%) | PCE (%) |
|---|---|---|---|---|
| Comparative | 0.61 | 9.30 | 0.65 | 3.70 |
| embodiment | | | | |
| Embodiment 1 | 0.61 | 10.20 | 0.59 | 3.66 |
| Embodiment 2 | 0.61 | 12.10 | 0.60 | 4.43 |
| Embodiment 3 | 0.61 | 11.10 | 0.62 | 4.19 |

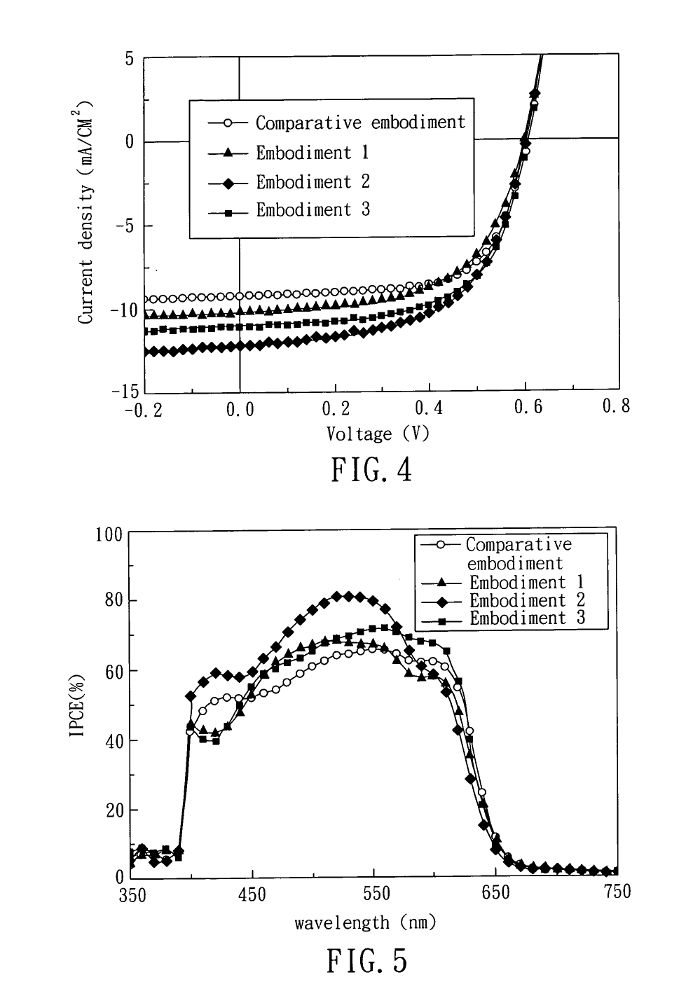

FIGS. 4 and 5 are the voltage-current density curves and IPCE curves of the test examples of the present invention, respectively. As shown in FIG. 4, the short-circuit current density of each solar cells prepared in Embodiments 1-3 are higher than that prepared in Comparative embodiment, and especially the solar cell prepared in the Embodiment 2 has the highest short-circuit current density. In addition, as shown in FIG. 5, the spectral response of the solar cells prepared in Embodiments 1-3 changed significantly, and the changes of the spectral response are resulted from the optical interference effects. Especially, the photocurrent of the solar cell of Embodiment 2 in the wavelength of 400-600 nm is much improved. Furthermore, according to the aforementioned table, the inverted organic solar cells containing the optical spacer prepared in Embodiments 1-3 have improved short-circuit current, and the power conversion efficiencies of the organic solar cells prepared in Embodiments 1-3 are improved greatly. Especially, the short circuit current of the inverted organic solar cell of Embodiment 2 can be improved from 9.30 mA/cm² to 12.10 mA/cm², and the power conversion efficiency can be improved from 3.70% to 4.43%.

In addition, compared to the inverted organic solar cell of Comparative embodiment, the maximum exciton generation rate (Gₘₐₓ) of the solar cell of Embodiment 2 can be improved from 4.13×10²⁷ m⁻³s⁻¹ to 4.97×10²⁷ m⁻³s⁻¹. The improved Gₘₐₓ indicated that the light absorption in the active layer can be enhanced with favorable thicknesses of the optical interfacial layer of ITO and the buffer layer of MoO₃, thereby the power conversion efficiency of the device can be improved.

In the conventional organic solar cell, the expected performance enhancement from the optical interference effect is negated when the thickness of the active layer exceeds 60 nm. However, when the thickness of the active layer is less than 60 nm, the light absorption in the active layer is decreased and it is difficult to achieve the purpose of providing an organic solar cell with high power conversion efficiency. On the contrary, according to the inverted organic solar cell containing an optical spacer of the present invention, the thickness of the active layer can be increased to 180 nm, and the light absorption can also be improved. Especially, according to the inverted organic solar cell containing an optical spacer of the present invention the power conversion efficiency can be improved greatly by setting an optical spacer with a favorable thickness. In addition, the acidic material, PEDOT, is not used in the inverted organic solar cell of the present invention, so the degradation of the device can be prevented, and the stability of the device can be improved.

Although the present invention has been explained in relation to its preferred embodiment, it is to be understood that many other possible modifications and variations can be made without departing from the scope of the invention as hereinafter claimed.

What is claimed is:

1. An inverted organic solar cell, comprising:
a substrate;
a first electrode disposed on the substrate;
an active layer disposed on the first electrode;
an optical spacer containing a buffer layer and an optical interfacial layer, wherein the buffer layer is laminated on the active layer, the optical interfacial layer is laminated on the buffer layer, and the buffer layer locates between the active layer and the optical interfacial layer; and
a second electrode disposed on the optical spacer.

2. The inverted organic solar cell as claimed in claim 1, further comprising: a modification layer disposed on the first electrode, wherein the modification layer locates between the first electrode and the active layer.

3. The inverted organic solar cell as claimed in claim 1, wherein the material of the optical interfacial layer is ITO, IZO, or titanium oxide.

4. The inverted organic solar cell as claimed in claim 1, wherein the material of the buffer layer is MoO₃, V₂O₅, or NiO.

5. The inverted organic solar cell as claimed in claim 2, wherein the material of the modification layer is Cs₂CO₃, ZnO, or titanium oxide.

6. The inverted organic solar cell as claimed in claim 1, wherein the material of the active layer is P3HT, PCBM, MDMO-PPV, or a combination thereof.

7. The inverted organic solar cell as claimed in claim 1, wherein the substrate is a glass substrate, a quartz substrate, or a plastic substrate.

8. The inverted organic solar cell as claimed in claim 1, wherein the first electrode is an ITO electrode, or an IZO electrode.

9. The inverted organic solar cell as claimed in claim 1, wherein the second electrode is a metal electrode.

10. The inverted organic solar cell as claimed in claim 1, wherein the thickness of the optical interfacial layer is 1-250 nm.

11. The inverted organic solar cell as claimed in claim 1, wherein the thickness of the buffer layer is 1-40 nm.

12. A method for manufacturing an inverted organic solar cell, comprising following steps:
(A) providing a substrate with a first electrode formed thereon;
(B) forming an active layer on the first electrode;
(C) forming a buffer layer, and an optical interfacial layer in sequence, wherein the buffer layer and the optical interfacial layer together compose an optical spacer; and
(D) forming a second electrode on the optical spacer.

13. The method as claimed in claim 12, further comprising a step (Al) after the step (A): forming a modification layer on the first electrode, wherein the modification layer locates between the first electrode and the active layer.

14. The method as claimed in claim 12, wherein the material of the optical interfacial layer is ITO, IZO, or titanium oxide.

15. The method as claimed in claim 12, wherein the material of the buffer layer is MoO₃, V₂O₅, or NiO.

16. The method as claimed in claim 13, wherein the material of the modification layer is Cs₂CO₃, ZnO, or titanium oxide.

17. The method as claimed in claim 12, wherein the material of the active layer is P3HT, PCBM, MDMO-PPV, or a combination thereof.

18. The method as claimed in claim 12, wherein the thickness of the optical interfacial layer is 1-250 nm.

19. The method as claimed in claim 12, wherein the thickness of the buffer layer is 1-40 nm.

20. The method as claimed in claim 12, wherein the optical interfacial layer is formed through a sputtering process, in the step (C).

21. The method as claimed in claim 12, wherein the active layer is formed through a spin coating process, a dip coating process, a roll coating process, or a printing process, in the step (B).

22. The method as claimed in claim 12, wherein the buffer layer is formed through an evaporation process, in the step (C).

23. The method as claimed in claim 12, wherein the second electrode in formed through an evaporation process, and the second electrode is a metal electrode, in the step (D).
